(19) United States
(12) Patent Application Publication
(10) Pub. No.: US 2014/0360429 A1
(43) Pub. Date: Dec. 11, 2014

(54) GAS BARRIER ELEMENT FOR PECVD REACTORS

(71) Applicant: TEL Solar AG, Trubbach (CH)

(72) Inventors: Devendra Chaudhary, Jagatpura (IN); Daniele Zorzi, Eschenbach (CH); Werner Wieland, Malans (CH); Markus Klindworth, Wangs (CH); Aurel Salabas, Gams (CH)

(21) Appl. No.: 14/298,518

(22) Filed: Jun. 6, 2014

Related U.S. Application Data
(60) Provisional application No. 61/831,661, filed on Jun. 6, 2013.

(51) Int. Cl. C23C 16/52; C23C 16/505; C23C 16/513

(52) U.S. Cl. CPC C23C 16/52; C23C 16/513; C23C 16/505
USPC 118/723 I

(57) ABSTRACT

This disclosure relates to plasma processing for photovoltaic device manufacturing. Particularly to a plasma processing system that includes an electrode that allows gas to pass through into the process chamber that includes a substrate. A gas barrier component may be used to minimize parasitic plasma occurring at the edges of the electrode by preventing process gas reaching the edge of the chamber or from entering the process chamber by going around the electrode. The gas barrier component may be made of a non-conductive flexible material that forms a fluidic seal between the electrode and the chamber. In other embodiments, the gas barrier may also support isolation grids that are disposed opposite of the electrode and prevent the isolation grids from moving.

### CROSS REFERENCE TO RELATED APPLICATION

Pursuant to 37 C.F.R. §1.78(a)(4), this application claims the benefit of and priority to prior filed co-pending Provisional Application Ser. No. 61/831,661 filed Jun. 6, 2013, which is expressly incorporated herein by reference.

### FIELD OF INVENTION

This application is related to a construction element enabling gas confinement and suppression of unwanted parasitic plasma behind a radio frequency (RF) electrode in a PECVD system working at pressures higher than 300 Pa.

### BACKGROUND

Ceramic elements work for low pressure regimes (<300 Pa), but do not achieve sufficient leak tightness in the sub-chamber behind the electrode when processing at higher pressures. Using ceramic elements may cause ignition of parasitic plasma at the edges of the electrode that may not be avoided at pressures >300 Pa and at typical gap distances between 1-8 mm between electrode and grounded parts.

### SUMMARY

High process pressure (e.g., >300 Pa) for depositing silicon layers on large (e.g., >1 m²) substrates, may result in unwanted process conditions. Silicon layer deposition may be done using plasma-enhanced chemical vapor deposition (PECVD) by energizing gas (e.g., plasma) that is opposite the substrate. The gas may be energized by an electrode that may also be opposite the substrate and may distribute the gas into the plasma processing region. In one instance, the gas may be distributed from a gas distribution plenum through the electrode. However, when the gas is confined behind the electrode it may produce unwanted parasitic plasma gas distribution plenum and in some eases arcing may occur at the edges of the electrode.

This application relates to a wall element manufactured from Teflon or other non-conductive material to form a fluid seal between the hot electrodes and grounded surfaces to suppress plasma ignition at working pressure higher than 300 Pa and to provide a pressure step of at least 2 Pa between the gas distribution plenum and the plasma processing region. In one specific embodiment, the gap distances are less than or equal to 8 mm. The pressure step may be 1 to 10 times the lateral pressure drop in a 1100×1300 mm² reactor, which can exceed 2 Pa at reactor pressures >300 Pa. Preferred values for the pressure step are 1-100 Pa, more preferred 5-50 Pa and even more preferred 25-35 Pa.

### BRIEF DESCRIPTION OF THE DRAWINGS

The accompanying drawings, which are incorporated in and constitute a part of this specification, illustrate embodiments of the invention and, together with a general description of the invention given above, and the detailed description given below, serve to explain the invention. Additionally, the left most digit(s) of a reference number identifies the drawing in which the reference number first appears.

FIG. 1 is an illustration of a representative embodiment of a plasma processing system that shows a schematic cross-sectional illustration of a plasma chamber that includes a power source assembly that uses an electrode to transmit microwave and. RF energy.

FIG. 2 is a schematic cross-sectional illustration of the power source assembly hat uses an electrode to generate inductively coupled plasma inside the plasma chamber.

### DETAILED DESCRIPTION

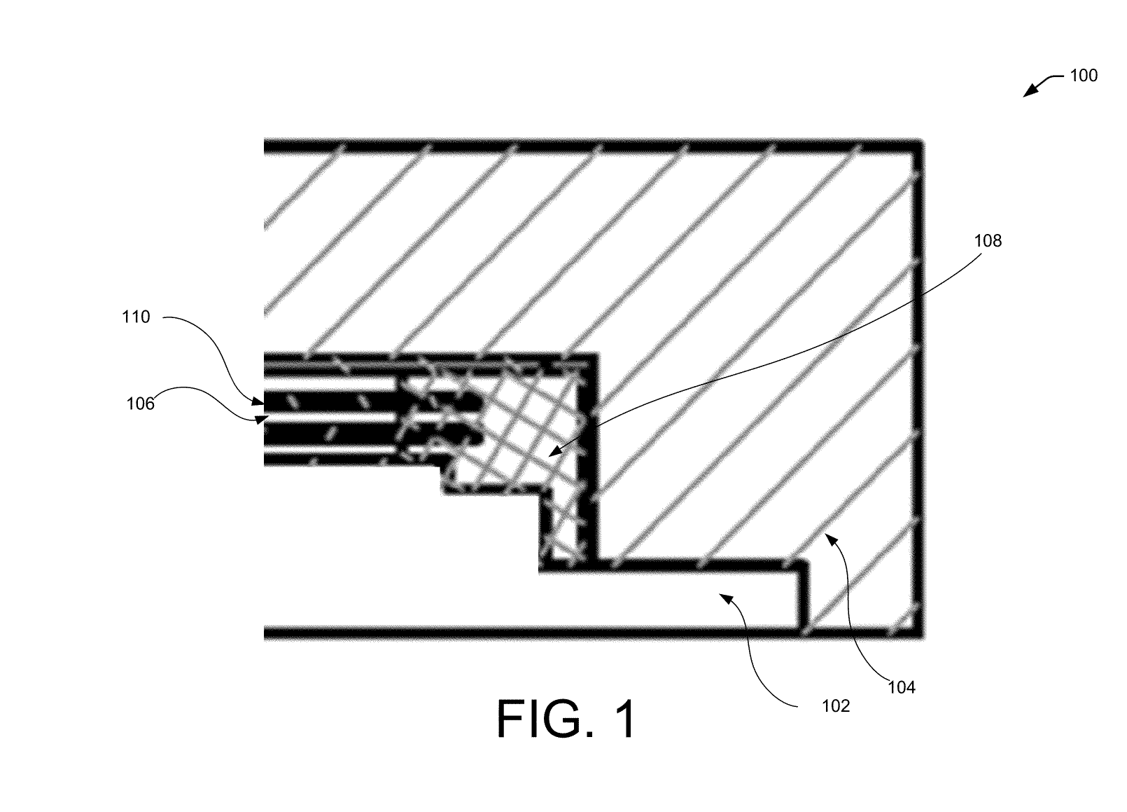

FIG. 1 is an illustration of a representative embodiment of a plasma processing system (not shown) that shows a schematic cross-sectional illustration of a plasma chamber that includes a power source assembly 100 that uses an electrode 102 to transmit radio frequency (R.F) energy into the plasma processing region of the plasma chamber. The electrode 102 may be electrically isolated from the plasma chamber using a ground barrier 104 that may prevent RF energy from being transmitted outside of the plasma processing region.

Generally, the plasma processing region may include a substrate holder for a substrate (e.g., glass or silicon) that receives a chemical vapor deposition treatment. It is well known that solar cells may be generated by depositing successive silicon (e.g., microcrystalline or amorphous, doped or undoped) layers. The substrates (not shown) may have a surface area of greater than 1 m². To achieve consistent silicon layer uniformity, gas and RF energy may be evenly distributed across the plasma processing region. In one embodiment, a gas distribution system may include a gas distribution plenum 106 disposed between the electrode 102 and a ground barrier 104 for the plasma chamber. The gas may be energized to generate plasma that may enable plasma-enhanced chemical vapor deposition on the substrate. However, in some instances, the gas may become energized in regions outside of the plasma processing regions (e.g., parasitic plasma), such as the gas distribution plenum 106, ground barrier 104, or other portions of the plasma chamber that are not desirable. At least two approaches may be used to prevent parasitic plasma, the first being to prevent gas distribution into small spaces where parasitic plasma is more likely to occur and the second being to prevent RF energy from being exposed to those small spaces and generating parasitic plasma.

In one embodiment, a gas barrier 108 comprising a flexible non-conductive material that can form a fluid seal between the electrode 102 and the ground barrier 104. The fluid seal may be formed between contacting surfaces of the gas barrier 108 and the electrode 102 and may prevent gas from being disposed in small areas between the electrode 102 and the ground barrier 104. The small areas may have gaps no more than 1 mm, The non-conductive material should be able to maintain the fluid seal under pressures of more than 300 Pa and temperatures of greater than 150 C. In one specific embodiment, the non-conductive material may include, but is not limited to, Polytetrafluoroethylene (e.g., Teflon®) or any other similarly situated plastic.

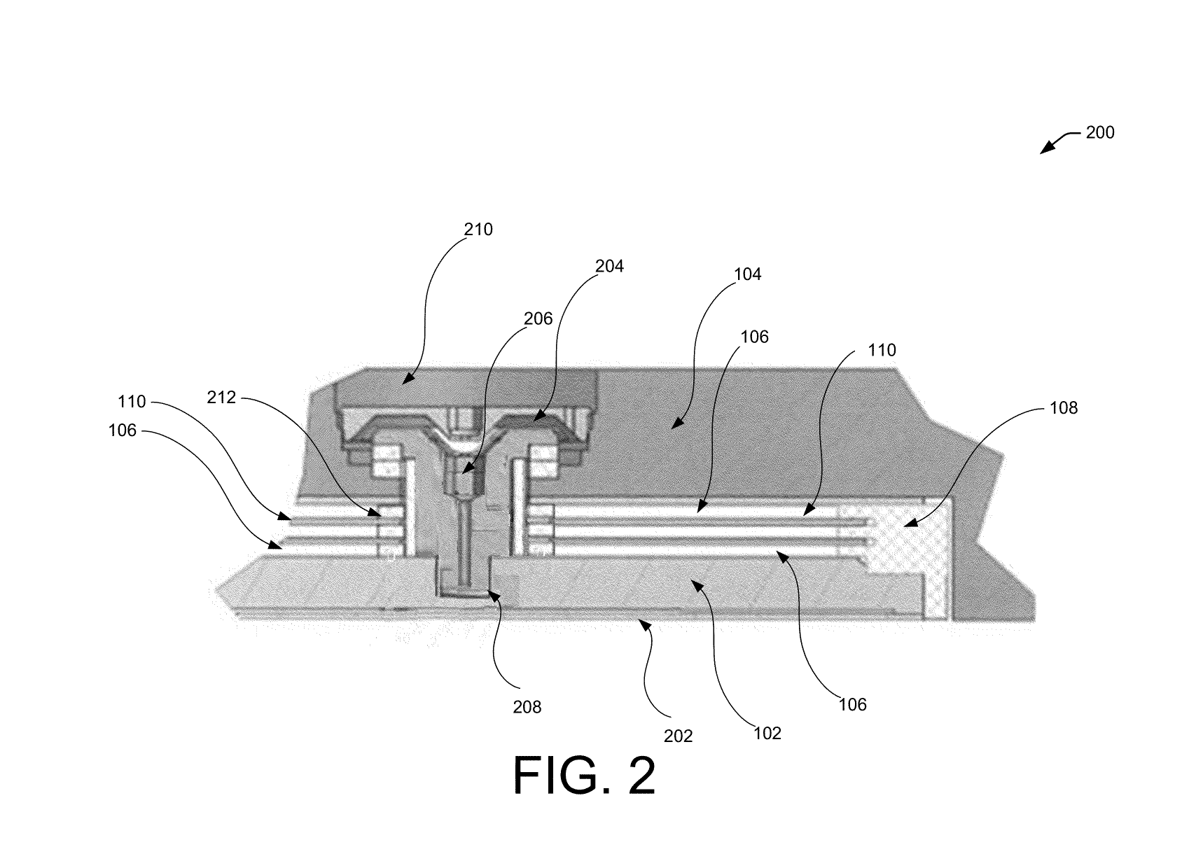

In another embodiment, the gas distribution plenum 106 may also include one or more isolation grids 110 that may prevent arcing between the electrode 102 and the ground barrier 104. The isolation grids may also prevent plasma generation within the gas distribution plenum 106. The isolation grids may be supported by the gas barrier 108 that may be arranged around the perimeter of the electrode 102. The isolation grid(s) 110 may form a mesh that may be permeable to the gas mixture within the gas distribution plenum 106. The gas distribution plenum 106 may also include two isolation grids 110 that are substantially parallel to each other and are coupled to the gas barrier 108. The isolation grids may be comprised of a conductive material that may include, but is not limited to, a metal that may be substantially unreactive to the gas at pressures greater than 300 Pa and temperatures greater than 150 C. In one specific embodiment, the gas distribution plenum 106 may be a gap of less than or equal to 16 mm between the electrode 102 and the ground barrier 104. The gap distance may be adjusted or controlled by mechanical means described in the description of FIG. 2.

FIG. 2 is a schematic cross-sectional illustration of the power source assembly 200 that uses an electrode 102 to generate inductively coupled plasma or surface wave plasma inside the plasma chamber. The power source assembly 200 may include a gas distribution plenum 106 that may distribute gas(es) across the surface of the electrode 102. Gas distribution holes 202 in the electrode 102 may be used to distribute gas to the plasma processing region opposite the electrode 102.

The gap of the gas distribution plenum 106 may be disposed between the ground barrier 104 and the electrode 102 and may be less than 16 mm, The gap may controlled by several indexing mechanisms that may be coupled to the ground barrier 104 and the electrode 102. One of the indexing mechanisms is illustrated in FIG. 2. A bracket arm 204 may secure the indexing mechanism to the ground barrier 104 and may also be coupled to an adjustable screw 206. The adjustable screw 206 may be coupled to the electrode 102 via a connection device 208 that may be of mechanical or magnetic means that enables the indexing mechanism to adjust the gap of the gas distribution plenum 106 by making adjustments to the adjustable screw 206. An index cover 210 may be removed to expose the adjustable screw 206 for adjustment purposes. The index cover 210 may also be used to protect the indexing mechanism during processing operations of the plasma chamber. The indexing mechanism may be electrically isolated from the electrode 102 to minimize the impact on the distribution of RF energy to the plasma processing region. Likewise, the indexing mechanism may be sealed off from the gas distribution plenum 106, such that gas may not eely flow into the indexing mechanism. Index gas barriers 212 may also form a fluidic seal between the indexing mechanism and the gas distribution plenum 106. The index gas barriers 212 may also support the isolation grids 110 and may be made of similar materials as the gas barrier 108.

In one embodiment, the gas barrier 108 may have a thickness that is optimized to fill the gap between the isolation grids 110 and the grounded surfaces and/or form the fluid seal under a certain range of process conditions. For example, the gas barrier 108 may expand to fill up the or close the gap to less than or equal to 0.5 mm under process conditions. The process conditions may include, but are not limited to, a temperature greater than 160 C and a pressure greater than 15 mbar, The gas barrier 108 may also be designed to minimize the horizontal level uniformity of the isolation grids 110 to be less than 0.5 mm across the chamber. Under these conditions, the horizontal and vertical movement of the isolation grids may be limited to less than 0.5 mm under the aforementioned processing conditions.

What is claimed is:

1. A system, comprising:
RF electrode comprising:
a power connector that is configured to be coupled to a radio frequency power generator; and
a plurality of holes that each have an opening on at least two sides of the electrode such that a gas can flow through one or more of the holes;
a ground component that surrounds a portion of the electrode;
a gas plenum that is formed between the electrode and ground component that can store the gas that can flow through the one or more holes of the electrode;
a non-conductive gas barrier disposed between a portion of the electrode and a portion of the ground component and that forms a fluid seal between the gas plenum the RF electrode;
a voltage dampening grid in the gas plenum that is coupled to the non-conductive gas barrier, and that increases the electrical isolation between the electrode and the ground component.

2. The system of claim 1, further comprising:
an electrode suspension component that is mechanically coupled to the electrode and comprises:
a portion of the electrode suspension component that traverses the gas plenum; and
an adjustment component that can control a distance between the electrode and the ground component; and
a non-conductive component that surrounds the portion of the electrode suspension component that traverses the gas plenum.

3. The system of claim 2, wherein the voltage dampening grid being, at least partially, supported by the non-conductive component,

4. The system of claim 1, wherein the insulating material comprises Polytetrafluoroethylene.

5. The system of claim 4, wherein the insulating material comprises:
at least one receptacle to support the voltage dampening grid; and
at least one heat expansion feature configured to compensate for thermal expansion of the insulating material.

6. The system of claim 5, wherein the electrode and the ground component being substantially square or substantially rectangular.

7. The system of claim 6, wherein the insulating material further comprises at least one corner component that conforms to at least one corner of the substantially square electrode or the substantially rectangular electrode.

8. The system of claim 1, further comprising a plasma processing region that is substantially separated from the gas plenum by the electrode and is configured to process substrates of at least 1 m², and the gas plenum and the plurality of holes being configured to maintain a pressure differential between the plasma processing region and the gas plenum of at least 2 Pa.

9. A plasma processing system, comprising:
a ground component comprising at least one ground pass-through for gas that is used to generate plasma;
a electrode that is mechanically suspended from the ground component and electrically insulated from the ground component, and comprises:
a perimeter that is no more than 6 mm. away from a surface of the ground component; and
at least one electrode pass-through for the gas to a plasma processing region configured for substrates comprising a surface area of at least 1 m²;
an insulating material disposed between the perimeter of the electrode and the surface of the ground component, the insulating material forming a gas flow resistant seal between the electrode and the ground component; and
one or more voltage dampening components suspended between the ground component and the electrode by, at least, the insulating material.

10. The plasma processing system of claim 9, wherein the insulating material comprises:
a compressible characteristic that enables the insulating material to be compressed between the ground component and he electrode to enable preventing the gas from flowing between the perimeter of the electrode and the surface of the ground component;
an insulating characteristic that at least minimizes electrical arcing between the electrode and the ground component near the perimeter of the electrode;
a chemical compatibility with fluorine under a temperature of at least 150 degrees Celsius;
at least one receptacle for each of the one or more voltage dampening components; and
a heat expansion feature that accommodates thermal expansion of the insulating feature.

11. The plasma processing system of claim 9, further comprising:
at least one mechanical suspension component coupled to the ground component and the electrode; and
at least one substantially cylindrical suspension insulating element that surrounds at least a portion of the at least one suspension component, the suspension insulating element configured to prevent plasma from forming proximate to the at least one suspension element.

12. The plasma processing system of claim 11, wherein the at least one suspension element is configured to support the one or more voltage dampening components.

13. The plasma processing system of claim 11, wherein the electrode comprises a substantially square geometry or a substantially rectangular geometry.

14. The plasma processing system of claim 9, wherein the insulating component comprises two or more interlocking components that are configured to accommodate thermal expansion of the two or more interlocking components

15. A plasma processing system, comprising:
a first electrical component comprising:
a connection to electrical ground;
a substantially square pocket comprising a surface area of at leas pocket being proximate to a center of the first electrical component; and
a coupling to a gas source;
a second electrical component that is disposed within the pocket and offset from the surface area of the pocket by at least 4 mm and no more than 20 mm;
at least one metal sheet component disposed between the first electrical component and the second electrical component; and
a sealing component disposed between the first electrical component and the second electrical component to prevent a gas from leaking between the first electrical component and the second electrical component, and to support, at least partially, the at least one metal component.

16. The plasma processing system of claim 15, herein the sealing component comprises:
two or more interlocking components that are configured to accommodate thermal expansion of the two or more interlocking components; and
at least one thermal expansion feature to compensate for thermal expansion of the sealing component to at least 150 degrees Celsius.

17. The plasma processing system of claim 15, wherein the sealing component comprises Polytetrafluoroethylene.

18. The plasma processing system of claim 15, further comprising suspension couplings that offset the second electrical component from the first electrical component.

19. The plasma processing system of claim 15, wherein the second electrical component comprises an electrode that is configured to generate plasma in the plasma processing system.

20. The plasma processing system of claim 15, wherein the second electrical component comprises a plurality of gas pass-through holes that enable a gas to diffuse through the second electrical component.
